(19) United States
(12) Patent Application Publication
(10) Pub. No.: US 2009/0189632 A1
(43) Pub. Date: Jul. 30, 2009

(54) Test board used for a reliability test and reliability test method

(75) Inventor: Shouta Kawano, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/314,141

(22) Filed: Dec. 4, 2008

(30) Foreign Application Priority Data
Jan. 29, 2008 (JP) 17827/2008

(51) Int. Cl. G01R 31/26

(52) U.S. Cl. 324/765

(57) ABSTRACT

To conduct a reliability test for a tape automated bonding (TAB) package under a state being close to a mounting state to a product, the TAB package (1) includes a TAB tape (3), a semiconductor chip (2) mounted on the TAB tape (3), and a first terminal (7a) and a second terminal (7b) formed on both end portions of the TAB tape (3), electrically connected to the semiconductor chip (2) through wiring. A test board (10) used for the reliability test for the TAB package (1) includes a substrate (20), a pair of holding members (30-1, 30-2) provided on the substrate 20 so as to face with each other for holding the respective both end portions of the TAB package (1), holding portion terminals each provided to each of the pair of holding members (30-1, 30-2) so as to have a contact with each of the first terminal (7a) and the second terminal (7b). A distance (L2) between the pair of holding members (30-1, 30-2) is shorter than a distance (L1) between the first terminal (7a) and the second terminal (7b) along a surface of the TAB package (1).

### BACKGROUND OF THE INVENTION

1. Field of the Invention

The present invention relates to a reliability test for a semiconductor device. In particular, the present invention relates to a reliability test for a tape automated bonding (TAB) package on which a semiconductor chip is mounted.

2. Description of the Related Art

A burn-in test is known as a reliability test for enhancing product reliability of a semiconductor device. The burn-in test is an acceleration test in which a product sample or a real product is operated under high temperature and high voltage circumstances, and a stress, which is severer than an actual use state, is applied thereto. With this test, an initial failure or a malfunction during manufacturing steps may be found within a short period of time. As a result, a percentage of defectiveness of the product in the market is reduced, and the product reliability is assured.

In the burn-in test, the semiconductor device as a test subject is mounted on a burn-in test board, and the burn-in test board is received in a chamber. Japanese Patent Application Laid-open No. 2000-55980 describes a burn-in test board having an object to facilitate attachment/detachment of the semiconductor device. On a print wiring board of the burn-in test board, an IC case is provided for positioning the semiconductor device and obtaining an electrical connection. Through a guide of the IC case, the positioning of the semiconductor device is carried out, and the electrical connection is securely established with a contact lever.

Japanese Patent Application Laid-open No. 05-160221 discloses a burn-in test for a semiconductor element, in which a tape automated bonding (TAB) tape is used. On both sides of the TAB tape extending in a longitudinal direction, multiple sprocket holes are arranged along the longitudinal direction. The semiconductor element is disposed near a center of the TAB tape, and test terminals of the semiconductor element are arranged in the vicinities of the sprocket holes on both sides of the semiconductor element. In other words, a direction from the test terminals toward the semiconductor element is orthogonal to the longitudinal direction of the TAB tape. A signal application device for applying a signal to the test terminals during the burn-in test is constructed so that the TAB tape, on which the semiconductor element is mounted, is pinched (sandwiched) from both front and rear surfaces. A shape of the signal application device may bend along the longitudinal direction of the TAB tape. In this case, the TAB tape pinched by the signal application device also bends along the longitudinal direction (direction orthogonal to direction from test terminals toward semiconductor element).

Japanese Patent Application Laid-open No. 11-312714 discloses a technology for carrying out the burn-in test without using burn-in test boards and sockets. According to the technology, the TAB tape, on which the multiple semiconductor chips are mounted, is input to a burn-in apparatus while being wound around a reel.

The inventor(s) of the present invention focuses his (their) attention(s) on the following fact. The TAB package which being a semiconductor package using the TAB tape is mounted on a product under a bending state from its nature in many cases. An example thereof is illustrated with reference to FIG. 1 to FIG. 3. FIG. 1 to FIG. 3 each illustrate a case where TAB packages 1 are mounted on the liquid crystal display device.

FIG. 1 illustrates a state of the TAB packages 1 before being bent. A liquid crystal display device 100 includes an LCD panel 110 and external devices 120. The TAB packages 1 are mounted on the liquid crystal display device 100 so that the LCD panel 110 and the external devices 120 are connected. A semiconductor chip (IC chip) 2 is mounted on each of the TAB packages 1.

FIG. 2 illustrates a cross-section taken along the line A-A′ of FIG. 1. The TAB package 1 is a package of the semiconductor chip 2, in which the TAB tape 3 is used. Wirings such as lead wires 4 and solder resists 5 are formed on the TAB tape 3, and the semiconductor chip 2 is electrically connected to the wirings. Further, for protection of the semiconductor chip 2 and the wirings, and for reinforcement of mechanical strength, sealing resins 6 are provided at peripheries of the semiconductor chip 2 and on the wirings. In addition, a first connection terminal 7a and a second connection terminal 7b are formed on the lead wires 4 on both end portions of the TAB package 1, respectively. The first connection terminal 7a and the second connection terminal 7b are electrically connected to the external device 120 and the LCD panel 110, respectively. Like this, the TAB package 1 couples between the LCD panel 110 and the external device 120. The LCD panel 110 and the external devices 120 are electrically connected to each other through the first connection terminal 7a, the second connection terminal 7b, wirings, and the semiconductor chip 2.

FIG. 3 schematically illustrates a state of a product, which is shipped to markets. As illustrated in FIG. 3, the external device 120 is arranged at a rear surface of the LCD panel 110, with the result that the TAB package 1 bends. In particular, it should be noted that the TAB package 1 bends along a direction from the first connection terminal 7a toward the second connection terminal 7b.

If the TAB package 1 bends, a stress generates at bonding sections between the sealing resins 6 and peripheries thereof (lead wires 4, solder resists 5, etc.). Owing to this bending stress, there may occur a case of “resin peeling” which is a phenomenon that the sealing resin 6 peels off. Besides, there is a fear in that a mechanical stress due to bending of the TAB package 1 or an electrical stress due to electrification may affect wiring connections between the semiconductor chip 2 and the connection terminals 7a and 7b. Those things all affect a life of the semiconductor device (TAB package 1). In other words, the bending of the TAB package 1 affects the life of the product to be shipped.

Accordingly, in order to enhance the reliability of the product to be shipped, it is preferred to conduct the reliability test not only for the semiconductor chip 2 but also for the TAB package 1, which is situated under a state being close to an actual mounting state as much as possible. In other words, as illustrated in FIG. 3, it is preferred to conduct the reliability test under the state in which the TAB package 1 bends along a direction from the first connection terminal 7a toward the second connection terminal 7b. However, in the above-mentioned related documents, it was not assumed (expected) to conduct the reliability test for such products under the state being close to an actual mounting state.

### SUMMARY OF THE INVENTION

Hereinafter, description is made of embodiments of the present invention by using numerals and symbols to be used in “Detailed Description of the Invention.” These numerals and symbols are added with parentheses so as to make corresponding relation between description of “What is claimed is” and description of “Detailed Description of the Invention.” However, it should be noted that those numerals and symbols may not be used for understanding a technical scope of the invention described in “What is claimed is.”

According to a first aspect of the present invention, there is provided a test board (10), which is used for a reliability test for a TAB package (1). The TAB package (1) includes a TAB tape (3), a semiconductor chip (2) mounted on the TAB tape (3), and a first terminal (7a) and a second terminal (7b) formed on both end portions of the TAB tape (3), electrically connected to the semiconductor chip (2) through wiring. The test board (10) according to the present includes a substrate (20), a pair of holding members (30-1, 30-2) provided on the substrate 20 so as to face with each other for holding the respective both end portions of the TAB package (1), holding portion terminals each provided to each of the pair of holding members (30-1, 30-2) so as to have a contact with each of the first terminal (7a) and the second terminal (7b). A distance (L2) between the pair of holding members (30-1, 30-2) is shorter than a distance (L1) between the first terminal (7a) and the second terminal (7b) along a surface of the TAB package (1). Thus, when at the time of the reliability test, the TAB package (1) bends along a direction from the first terminal (7a) toward the second terminal (7b).

According to a second aspect of the present invention, there is provided a reliability test method for a tape automated bonding (TAB) package (1). The TAB package (1) includes a TAB tape (3); a semiconductor chip (2) mounted on the TAB tape (3); and a first terminal (7a) and a second terminal (7b) formed on both end portions of the TAB tape (3), respectively and electrically connected to the semiconductor chip (2) through wiring. The reliability test method of the present invention includes: (A) a step of fixing the both end portions of the TAB package (1) to a test board (10) so that the TAB package (1) bends along a direction from the first terminal (7a) toward the second terminal (7b); and a step of conducting a reliability test while supplying power to the semiconductor chip (2) through the first terminal (7a) and the second terminal (7b).

According to the present invention, it is possible to conduct the reliability test for the TAB package under a state being close to a mounting state to a product. As a result, accuracy of the reliability test is improved, and the reliability of the products to be shipped is enhanced.

### BRIEF DESCRIPTION OF THE DRAWINGS

In the accompanying drawings:

FIG. 1 is a conceptual diagram for illustrating a case where a TAB package is installed in the liquid crystal display device;

FIG. 2 is a cross-sectional view taken along the line A-A′ of FIG. 1;

FIG. 3 is a schematic diagram illustrating a state where the TAB package is curved in a product;

FIG. 4 is a cross-sectional view illustrating a TAB package as a test object according to an embodiment of the present invention;

FIG. 5 is a top view of a burn-in test board according to an embodiment of the present invention;

FIG. 6 is a cross sectional view illustrating a structure of a socket of the burn-in test board according to the embodiment of the present invention;

FIG. 7 is a schematic diagram illustrating an open/close state of a pair of the sockets according to an embodiment of the present invention;

FIG. 8 is a cross-sectional view illustrating a state of the socket at the time of a burn-in test according to an embodiment of the present invention; FIG. 9 is a schematic diagram illustrating an outer appearance of the TAB package at the time of the burn-in test according to the embodiment of the present invention; and

FIG. 10 is a side view illustrating a state of the TAB package at the time of the burn-in test according to the embodiment of the present invention.

### DESCRIPTION OF THE PREFERRED EMBODIMENT

Description is made of an embodiment of the present invention with reference to drawings.

1. TAB Package

A TAB package is a semiconductor package, which is based on a TAB technology, and a film-like TAB tape is used in place of a print wiring board. A plurality of semiconductor chips are mounted on one TAB tape, and bonding and packaging are carried out. After that, the TAB tape is cut at given intervals, whereby a plurality of TAB packages are produced. One TAB package contains at least one semiconductor chip.

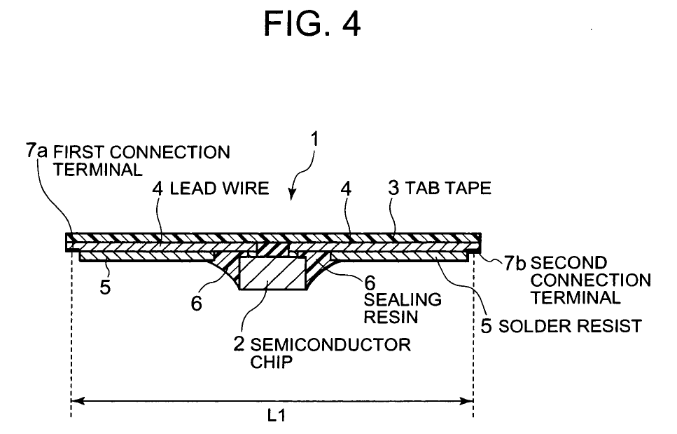

FIG. 4 illustrates an example of the TAB package according to an embodiment of the present invention. The TAB package 1 includes a semiconductor chip (IC chip) 2 mounted thereon. More specifically, wirings such as lead wires 4 and solder resists 5 are formed on a TAB tape 3, and the semiconductor chip 2 is electrically connected to the wirings. Further, for protection of the semiconductor chip 2 and the wirings, and for reinforcement of mechanical strength, sealing resins 6 are provided at peripheries of the semiconductor chip 2 and on the wirings. In addition, a first connection terminal 7a and a second connection terminal 7b are formed on the lead wires 4 on both end portions of the TAB package 1, respectively. In other words, the first connection terminal 7a and the second connection terminal 7b, which are electrically connected to the semiconductor chip 2 through the wirings, are formed on both end portions of the TAB package 1. A distance between the first connection terminal 7a and the second connection terminal 7b along a surface of the TAB package 1 is represented by “L1”.

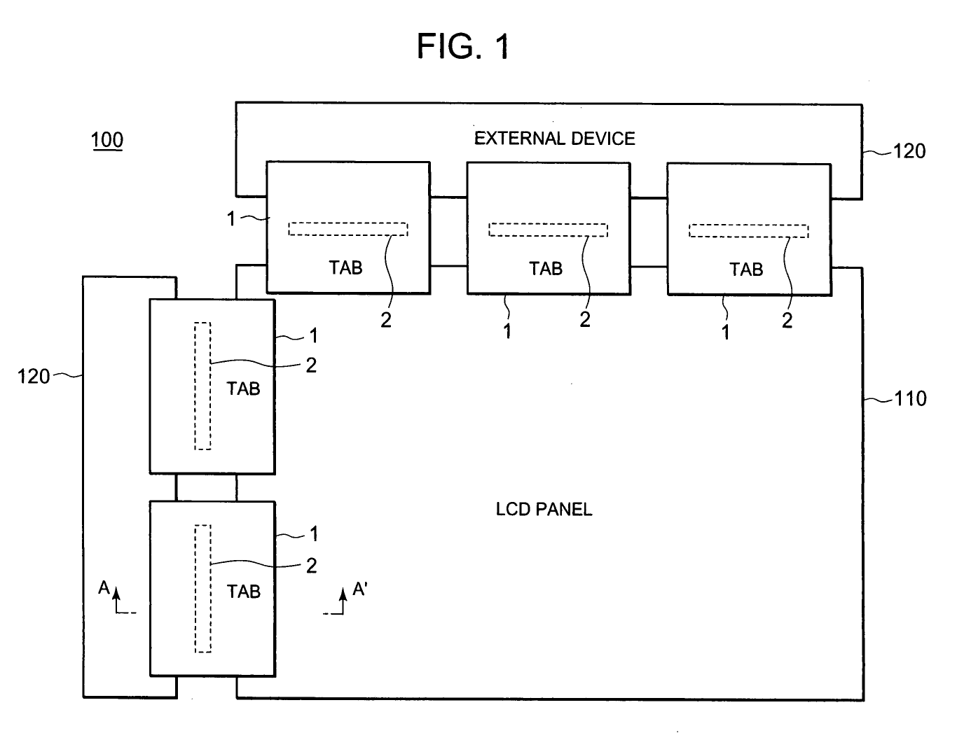

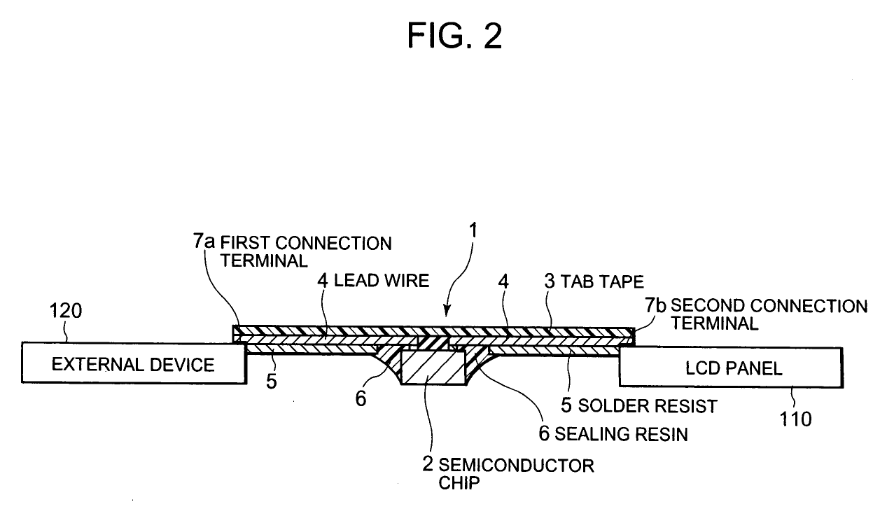

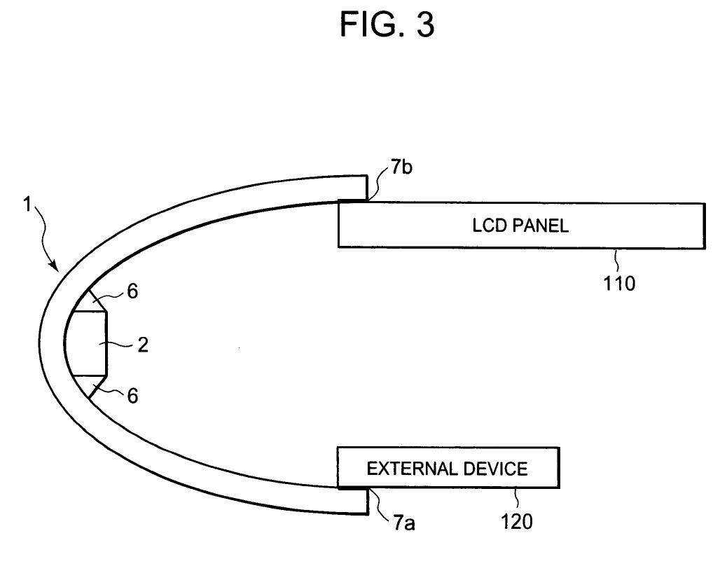

The TAB package 1 is mounted on a product under a bending state from its nature in many cases. As illustrated in FIG. 1 to FIG. 3 already described above, for example, the TAB packages 1 are mounted on a liquid crystal display device 100. In this case, the first connection terminal 7a and the second connection terminal 7b are electrically connected to external devices 120 and an LCD panel 110. As illustrated in FIG. 3, in the products shipped to markets, the TAB package 1 bends along a direction from the first connection terminal 7a toward the second connection terminal 7b. As described above, such bending of the TAB package 1 affects a life of the product.

In order to enhance the reliability of the product to be shipped, it is preferred to conduct the reliability test not only for the semiconductor chip 2 but also for the TAB package 1, which is situated under a state being close to an actual mounting state as much as possible. In other words, it is preferred to conduct the reliability test under a state in which the TAB package 1 bends along a direction from the first connection terminal 7a toward the second connection terminal 7b. According to an embodiment of the present invention, there may be provided a test board for the reliability test, with which the above-mentioned object may be attained. Hereinafter, a burn-in test is exemplified as the reliability test, and a burn-in test board, which is used in the burn-in test, is described.

2. Burn-In Test Board

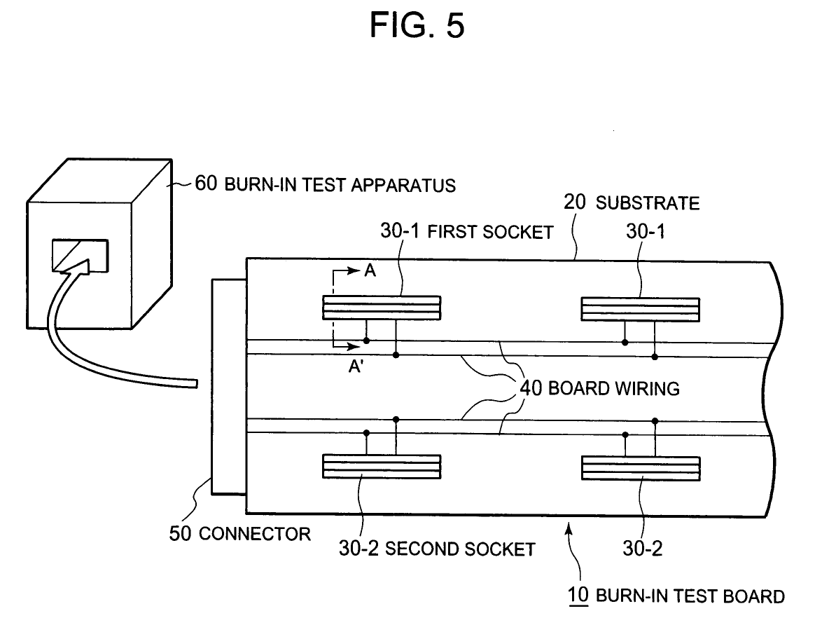

FIG. 5 is a top view illustrating a burn-in test board 10 according to an embodiment of the present invention. During the burn-in test, the burn-in test board 10, on which the TAB package 1 is mounted, is received in a chamber of a burn-in test apparatus (reliability test apparatus) 60 for conducting the burn-in test.

As illustrated in FIG. 5, the burn-in test board 10 includes a substrate 20 and first sockets 30-1 and second sockets 30-2 disposed on the substrate 20. The first sockets 30-1 and the second sockets 30-2 are holding members for holding the TAB package 1, and are disposed on the substrate 20 so as to face with each other. One of the first sockets 30-1 and one of the second sockets 30-2 are used as a socket pair for holding one TAB package 1. Both end portions of the TAB package 1 are mounted to the facing pair of sockets 30-1 and 30-2, respectively.

Further, board wirings 40 are formed in the substrate 20. The board wirings 40 are electrically connected to terminals formed in (provided to) the sockets 30-1 and 30-2, and are also connected to a connector 50 for establishing connection with a burn-in test apparatus 60. During the burn-in test, the connector 50 is connected to the burn-in test apparatus 60, and power or a signal is supplied from the burn-in test apparatus 60 through the board wiring 40.

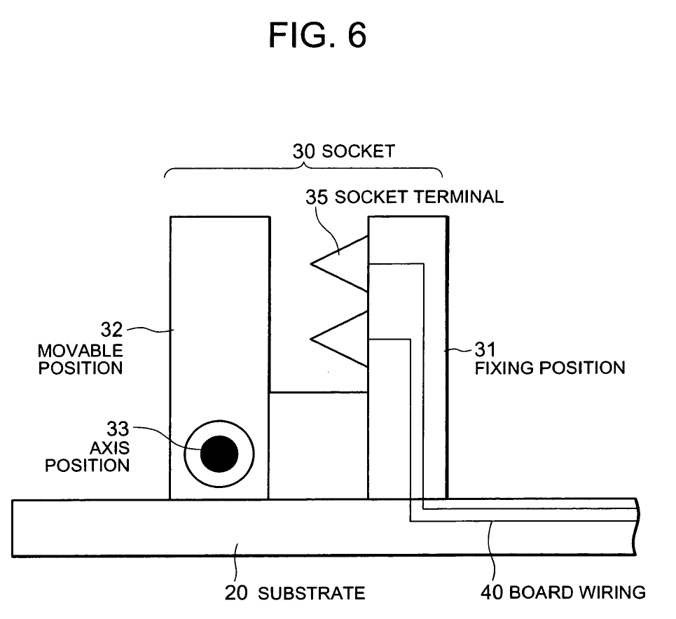

FIG. 6 is a cross-sectional view taken along the line A-A′ of FIG. 5, in which a structure of one socket 30 is illustrated in magnification. The socket 30 includes a fixing portion 31 and a movable portion 32. The fixing portion 31 is fixed to the substrate 20. On the other hand, the movable portion 32 is coupled to the fixing portion 31 via an axis portion 33, and is movable with respect to the fixing portion 31. In other words, the socket 30 is constructed so as to be openably and closably, and the TAB package 1 is pinched (sandwiched) by the fixing portion 31 and the movable portion 32.

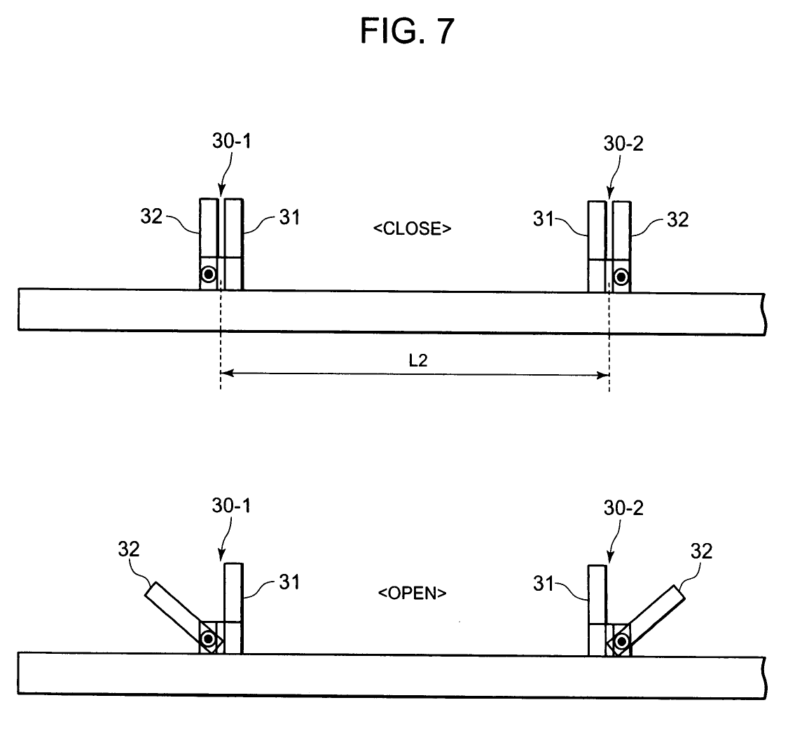

FIG. 7 illustrates an opened state and a closed state of the pair of sockets 30-1 and 30-2. During the closed state, the both end portions of the TAB package 1 are pinched (sandwiched) by the first socket 30-1 and the second socket 30-2, respectively, to be fixed. A locking mechanism (not shown) for maintaining the closed state may be provided to the respective sockets 30. Note that, as illustrated in FIG. 7, the distance between the pair of sockets 30-1 and 30-2 is represented by “L2.”

Referring to FIG. 6 again, socket terminals (holding portion terminals) 35 are provided to the respective socket 30. More specifically, the socket terminals 35 are formed on a side wall of the fixing portion 31 of the respective sockets 30. The socket terminals 35 are connected to the board wirings 40, and are used for supplying power or a signal to the TAB package 1. In other words, the socket terminals 35 are brought into contact with the first connection terminals 7a or the second connection terminals 7b of the TAB package 1. The socket terminals 35 of the first socket 30-1 are brought into contact with the first connection terminals 7a of one end portion of the TAB package 1, and the socket terminals 35 the second socket 30-2 are brought into contact with the second connection terminals 7b of another end portion of the TAB package 1.

3. Burn-In Test

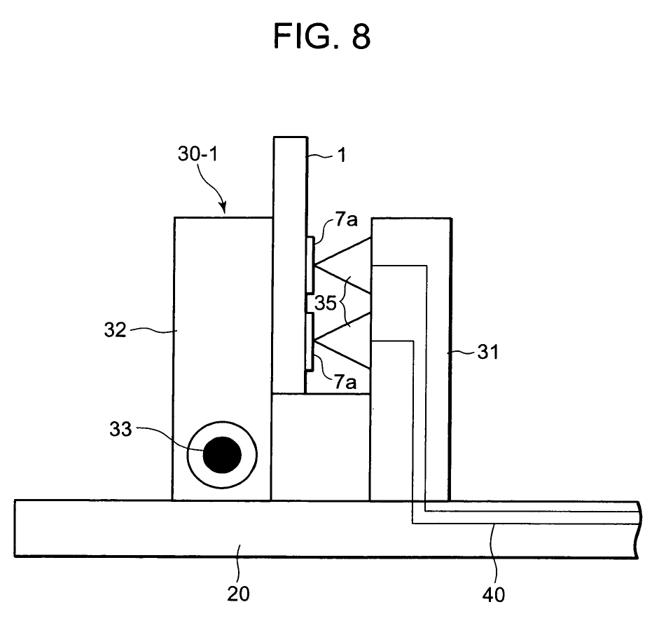

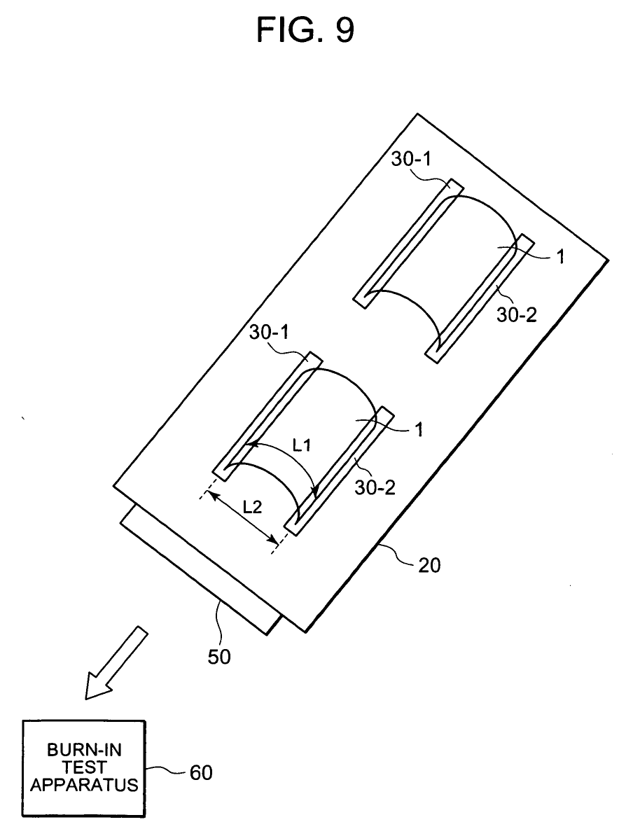

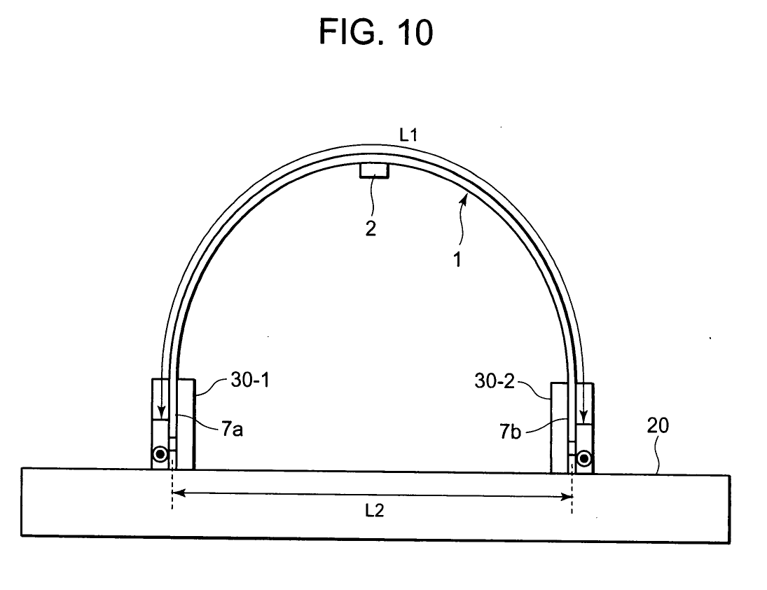

Next, by referring FIG. 8 to FIG. 10, a burn-in test according to an embodiment of the present invention is described. FIG. 8 corresponds to FIG. 6 that has already been described, and illustrates a state where an end portion of the TAB package 1 is fixed by the socket 30. FIG. 9 schematically illustrates an outer appearance of the TAB package 1 during the burn-in test. FIG. 10 is a side view illustrating a state of the TAB package 1 during the burn-in test.

During the burn-in test, the both end portions of the TAB package 1 are fixed to the burn-in test board 10. More specifically, both end portions of one TAB package 1 are held by one first socket 30-1 and one second socket 30-2, respectively, which are facing with each other. In this case, as illustrated in FIG. 8, the first connection terminals 7a of one end portion of the TAB package 1 are brought into contact with the socket terminals. 35 of the first socket 30-1. Similarly, the second connection terminals 7b of another end portion of the TAB package 1 are brought into contact with the socket terminals 35 of the second socket 30-2. The end portion of the TAB package 1 is pinched (sandwiched) by the fixing portion 31 and the movable portion 32, and hence an electrical connection between the socket terminals 35 and the connection terminals 7a and 7b is securely established.

As illustrated in FIG. 9 and FIG. 10, a distance “L2” between a pair of the sockets 30-1 and 30-2 for holding one TAB package 1 is smaller than a distance “L1” between the first connection terminal 7a and the second connection terminal 7b along a surface of the TAB package 1. Accordingly, if the both end portions of the TAB package 1 are fixed by one set of the sockets 30-1 and 30-2, the TAB package 1 bends. In particular, as illustrated in FIG. 10, the TAB package 1 bends along a direction from the first connection terminal 7a toward the second connection terminal 7b. Specifically, as illustrated in FIG. 3, a state, which is close to an actual mounting mode of a product, is reproduced. This bending of the TAB package 1 is actively produced while taking a mounting state into a consideration, and a curvature thereof is, for example, much larger than a curvature of a reel, which is used for carrying the TAB tape.

Under such a state, the burn-in test board 10, on which the TAB package 1 is mounted, is received in a chamber of the burn-in test apparatus 60. The connector 50 of the burn-in test board 10 is connected to the burn-in test apparatus 60. An electrical connection between the TAB package 1 and the burn-in test apparatus 60 is established through the socket terminals 35 and the board wirings 40. Power or a signal output from the burn-in test apparatus 60 is supplied to the semiconductor chip 2 through the burn-in test board 10, the socket terminals 35, the first connection terminals 7a, and the second connection terminals 7b. Like this, the burn-in test is carried out under a state in which power supply to the semiconductor chip 2 is conducted.

4. Effects

As described above, according to the embodiment of the present invention, there may be carried out the burn-in test for the TAB package 1 while taking the mounting state to the product into a consideration, which is not a simple burn-in test for the semiconductor chip 2.

To that end, in the burn-in test board 10 according to the embodiment of the present invention, design is conducted so that a distance “L2” between the pair of sockets 30-1 and 30-2 for holding the TAB package becomes smaller than a distance “L1” between the first connection terminal 7a and the second connection terminal 7b along the surface of the TAB package 1. Employment of the burn-in test board 10 described above enables to fix the TAB package 1 so as to bend in a direction from the first connection terminal 7a toward the second connection terminal 7b. In other words, the burn-in test may be carried out under the state being closed to the mounting state to the product, as illustrated in FIG. 3.

Note that, in the above-mentioned Japanese Patent Application Laid-open No. 05-160221, there is disclosed a signal application device having a shape bending along a longitudinal direction of the TAB tape as an example. In this case, the TAB tape, which is pinched (sandwiched) by the signal application device, also bends along the longitudinal direction. However, the longitudinal direction is an orthogonal direction with respect to a direction from the test terminal toward the semiconductor element. Thus, the bending direction differs from the bending direction of the embodiment of the present invention, it is not possible to obtain the effect owing to the embodiment of the present invention.

According to the embodiment of the present invention, it is possible to carry out the reliability test for the TAB package 1 under the state being close to the mounting state to the produce. As a result, accuracy of the reliability test may be improved to enhance the reliability of the products to be shipped. In addition, the burn-in test board 10 is realized with a simple structure, thereby being less expensive, and being easy in replacements of the parts.

As described above, the embodiment of the present invention has been described with reference to the drawings. However, the present invention is not limited to the embodiment described above, and may be appropriately modified by a person skill in the art without departing from a gist of the present invention.

What is claimed is:

1. A test board, which is used for a reliability test for a tape automated bonding (TAB) package comprising: a tape automated bonding (TAB) tape; a semiconductor chip mounted on the TAB tape; and a first terminal and a second terminal formed on both end portions of the TAB tape, respectively and electrically connected to the semiconductor chip through wiring,
the test board comprising:
a substrate;
a pair of holding members provided on the substrate so as to face with each other, for holding the respective both end portions of the TAB package; and
holding portion terminals each provided to each of the pair of holding members so as to have a contact with each of the first terminal and the second terminal,
wherein a distance between the pair of holding members is shorter than a distance between the first terminal and the second terminal along a surface of the TAB package.

2. A test board according to claim 1, wherein, when at a time of the reliability test, the pair of holding members holds the both end portions so that the TAB package bends along a direction from the first terminal toward the second terminal.

3. A test board according to claim 1, wherein, when at the time of the reliability test, power is supplied to the semiconductor chip through the holding portion terminals, and the first terminal and the second terminal.

4. A test board according to claims 1,
wherein each of the pair of holding members comprises: a fixing portion fixed on the substrate; and a movable portion fixed to the fixing portion, and
wherein the fixing portion and the movable portion are formed so as to sandwich the TAB package.

5. A test board according to claims 1, wherein the TAB package is mounted on a display device.

6. A test board, which is used for a reliability test for a tape automated bonding (TAB) package comprising: a tape automated bonding (TAB) tape; a semiconductor chip mounted on the TAB tape; and a first terminal and a second terminal formed on both end portions of the TAB tape, respectively and electrically connected to the semiconductor chip through wiring,
the test board comprising:
a substrate;
a pair of holding members provided on the substrate so as to face with each other, for holding the respective both end portions of the TAB package; and
holding portion terminals each provided to each of the pair of holding members so as to have a contact with each of the first terminal and the second terminal,
wherein, when at a time of the reliability test, the pair of holding members holds the both end portions so that the TAB package bends in a direction from the first terminal toward the second terminal.

7. A reliability test method for a tape automated bonding (TAB) package comprising: a tape automated bonding (TAB) tape; a semiconductor chip mounted on the TAB tape; and a first terminal and a second terminal formed on both end portions of the TAB tape, respectively and electrically connected to the semiconductor chip through wiring, the method comprising the steps of:
fixing the both end portions of the TAB package to a test board so that the TAB package bends along a direction from the first terminal toward the second terminal; and
conducting a reliability test while supplying power to the semiconductor chip through the first terminal and the second terminal.
